(19) United States
(12) Patent Application Publication
(10) Pub. No.: US 2006/0267215 A1
(43) Pub. Date: Nov. 30, 2006

(54) Semiconductor device, semiconductor device mounting board, and method for mounting semiconductor device

(76) Inventors: Hideki Ogawa, Hino-shi (JP); Kuniyasu Hosoda, Hanno-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/444,068

(22) Filed: May 31, 2006

(30) Foreign Application Priority Data
May 31, 2005 (JP) 2005-160661

(51) Int. Cl. H01L 23/48

(52) U.S. Cl. 257/778

(57) ABSTRACT

According to one embodiment, a semiconductor device includes an interposer board having a rectangular shape, a semiconductor chip provided on a front surface of the interposer board, projecting electrodes provided in a area on a back surface of the interpose board and electrically connected to the semiconductor chip, and auxiliary pins provided in corners of the back surface of the interposer board which corners are located outside the area, the auxiliary pins having a melting point of at least 250° C.

### CROSS-REFERENCE TO RELATED APPLICATIONS

This application is based upon and claims the benefit of priority from Japanese Patent Application No. 2005-160661, filed May 31, 2005, the entire contents of which are incorporated herein by reference.

### BACKGROUND

1. Field

One embodiment of the invention relates to a semiconductor device in a BGA package, an electronic part in which the semiconductor device is mounted, and a method for mounting the semiconductor device.

2. Description of the Related Art

An increasing number of semiconductor device products use ball grid arrays (BGAs) for packaging. A BGA package has ball-like projecting electrodes two-dimensionally arranged on a back surface of the device. Each of the electrodes is electrically connected to the semiconductor chip.

If a semiconductor device in a BGA package is mounted on a printed circuit board, mechanical stress is likely to act on projections located in the corners of the device. If the stress results in microcracks in any projecting electrodes, the semiconductor device is electrically disconnected from the printed circuit board.

A technique has been disclosed which suppresses generation of microcracks in the projecting electrodes located close to the corners (Jpn. Pat. Appln. KOKAI Publication No. 9-162241). This document states that reinforcing projections (solder) not electrically connected to the semiconductor chip are provided in the corners to reduce the stress on the electrodes located adjacent to the corners.

The above configuration reduces the stress on the projecting electrodes to suppress generation of microcracks. However, the reinforcing projections increase the external size of the semiconductor device. For mobile apparatuses such as personal computers, efforts have been made to reduce the area of the printed circuit board so as to improve portability. However, the increase in the external size of the semiconductor device makes it difficult to reduce the area of the printed circuit board.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1A, FIG. 1B, and FIG. 1C are an exemplary diagram showing the configuration of a semiconductor device in accordance with a first embodiment;

FIG. 2 is an exemplary diagram showing a electronic part composed of the semiconductor device shown in FIG. 2 which is mounted on a printed circuit board;

FIG. 3A, FIG. 3B, FIG. 3C, and FIG. 3D are an exemplary diagram showing a method for mounting the semiconductor device in accordance with the first embodiment;

FIG. 4 is an exemplary diagram showing a semiconductor device in accordance with a second embodiment mounted on a printed circuit board;

FIG. 5A, FIG. 5B, and FIG. 5C are an exemplary diagram showing a method for mounting the semiconductor device in accordance with the second embodiment;

FIG. 6 is an exemplary diagram showing the configuration of a semiconductor device in accordance with a third embodiment;

FIG. 7 is an exemplary diagram showing an electronic part composed of the semiconductor device shown in FIG. 6 which is mounted on a printed circuit board; and

FIG. 8A, FIG. 8B, and FIG. 8C are an exemplary diagram showing a method for mounting the semiconductor device in accordance with the third embodiment.

### DETAILED DESCRIPTION

Various embodiments according to the invention will be described hereinafter with reference to the accompanying drawings. In general, according to one embodiment of the invention, a semiconductor device comprises, an interposer board having a rectangular shape, a semiconductor chip provided on a front surface of the interposer board; projecting electrodes provided in a first area on a back surface of the interpose board and electrically connected to the semiconductor chip; and auxiliary pins provided in corners of the back surface of the interposer board which corners are located outside the first area, the auxiliary pins having a melting point of at least 250° C.

### FIRST EMBODIMENT

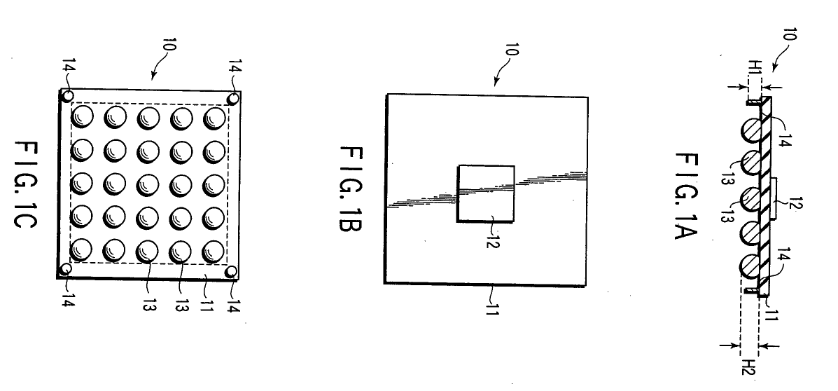

FIGS. 1A to 1C are a diagram showing the configuration of a semiconductor device in accordance with a first embodiment of the present invention. FIG. 1A is a side view of the semiconductor device. FIG. 1C is a plan view of a bottom surface of the semiconductor device. FIG. 1B is a plan view of a top surface of the semiconductor device.

As shown in FIGS. 1A to 1C, a semiconductor device 10 in a BGA package has a rectangular interposer board 11, a semiconductor chip 12, solder balls 13, and auxiliary pins 14. The semiconductor chip 12 is mounted on a front surface of the interposer board 11. The plurality of solder balls 13 are two-dimensionally arranged in a dotted first area on a back surface of the interposer board 11. Signal lines on the semiconductor chip 12 are electrically connected to the solder balls 13 via through vias formed in the interposer board 11.

The auxiliary pins 14 are provided in the four corners of the back surface of the interposer board 11, which are located outside the first area of the interposer board. The auxiliary pins 14 are composed of a material having a melting point higher than a reflow heating temperature so as not to melt during reflow. The auxiliary pins 14 are thus made of a metal material of a high melting point (at least 250° C.). The auxiliary pins 14 are made of, for example, a base material of a copper-based metal which is plated with Ni or Ni/Au, or a Sn-plated SUS-based base material. Alternatively, a high-melting-point solder may be used for the auxiliary pins 14. The auxiliary pins 14 have a height Hi smaller than that H2 of the solder balls 13.

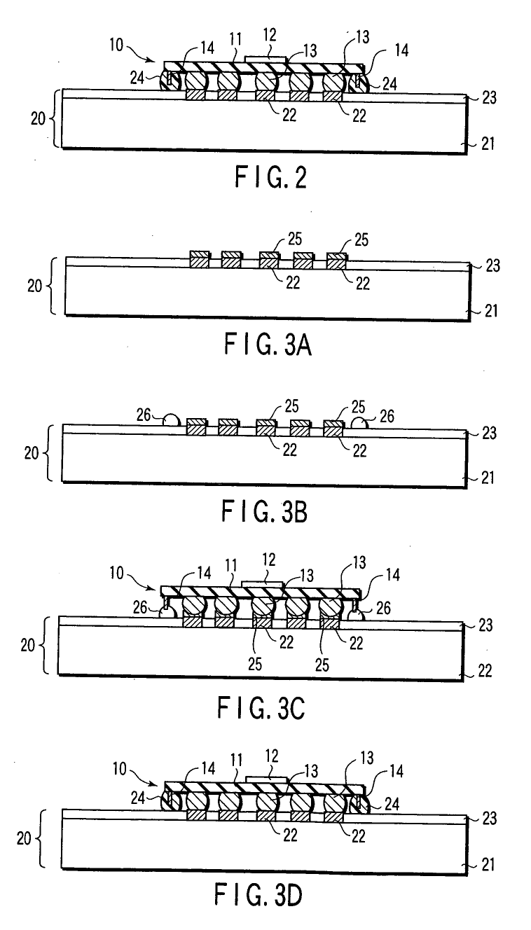

FIG. 2 shows an electronic part composed of the semiconductor device 10 shown in FIGS. 1A to 1C which are mounted on a printed circuit board.

A printed circuit board 20 is provided with a multilayer wiring board 21 containing interlayer wiring, and a plurality of pads 22 provided on the multilayer wiring board 21 and corresponding to positions where the corresponding solder balls 13 are arranged. Front wiring is provided on a front surface of the multilayer wiring board 21. A coat layer 23 is provided in those areas on the multilayer wiring board 21 which do not contain the pads 22 or front wiring.

The semiconductor device 10 is mounted on the printed circuit board 20. The solder balls 13 on the semiconductor device 10 are connected to the corresponding pads 22 on the printed circuit board 20. The auxiliary pins 14 are fixed to the printed circuit board 20 using a bonding member 24.

Since the bonding member 24 is used to fix the auxiliary pins 14 provided in the corners of the BGA package to the printed circuit board 20, the corners of the semiconductor device 10 are reinforced to reduce the stress on the corners. The solder balls 13 located close to the corners are thus unlikely to undergo microcracking. This improves the reliability of the semiconductor device concerning mechanical stresses.

The auxiliary pins 14 are used to reinforce the corners. The small diameter of the auxiliary pins 14 prevents the external size of the semiconductor device from being significantly increased. This enables the suppression of an increase in the area of the printed circuit board 20.

Now, a mounting method will be described with reference to FIGS. 3A to 3D.

As shown in FIG. 3A, solder paste 25 is printed on the pads 22, on which a surface mounted electronic part including the semiconductor device 10 is to be mounted.

As shown in FIG. 3B, when the semiconductor device 10 is mounted on the coat layer 23, a thermosetting adhesive 26 is applied to the areas in which the auxiliary pins 14 are located.

As shown in FIG. 3C, the semiconductor device 10 is mounted on the printed circuit board 20.

Reflow heating is then carried out to form an alloy layer of the solder balls 13, solder paste 25, and pads 22 as shown in FIG. 3D. The solder balls 13 are thus connected to the corresponding pads 22. The temperature for the reflow heating is normally lower than 250° C. During the reflow heating, the thermosetting adhesive 26 hardens to become a bonding member 24. The bonding member 24 hardens so as to wrap the auxiliary pins 14. The semiconductor device 10 is fixed to the printed circuit board 20 via the auxiliary pins 14 and the bonding member 24.

The auxiliary pins 14 are composed of a material with a melting point of at least 250° C. The temperature for the reflow heating is lower than 250° C. Consequently, the auxiliary pins 14 do not melt during reflow heating. Therefore, even after the reflow heating, the auxiliary pins 14 and the bonding member 24 reduce the stress on the corners of the semiconductor device 10.

### SECOND EMBODIMENT

In the first embodiment, the thermosetting bonding member is used to fix the semiconductor device 10 to the printed circuit board 20. In the present embodiment, description will be given of a method of using solder to fixing the semiconductor device 10 to the printed circuit board.

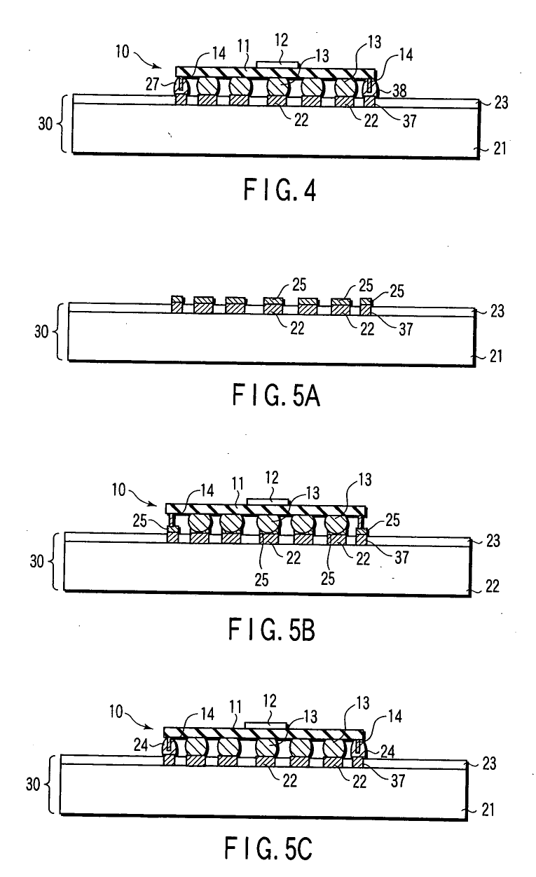

FIG. 4 shows the semiconductor device 10 mounted on the printed circuit board 30. In FIG. 4, the same areas as those in FIG. 2 are denoted by the same reference numbers and their description is omitted.

As shown in FIG. 4, dummy pads 37 are provided on a front surface of the printed circuit board 30. The dummy pads 37 are not electrically connected to the front wiring. The auxiliary pins 14 on the semiconductor device 10 are fixed to the corresponding dummy pads 37 via solder 38. An alloy layer is formed at the interface between each auxiliary pin 14 and the solder 38 and at the interface between each dummy pad 37 and the solder 38.

Since the solder 38 is used to fix the auxiliary pins 14 provided in the corners of the BGA package to the printed circuit board 30, the corners of the semiconductor device 10 are reinforced to reduce the stress on the corners. The solder balls 13 located close to the corners are thus unlikely to undergo microcracking. This improves the reliability of the semiconductor device concerning mechanical stresses.

Now, with reference to FIGS. 5A to 5C, description will be given of a method of mounting the semiconductor device 10 on the printed circuit board 30.

As shown in FIG. 5A, the solder paste 25 is printed on the pads 22, on which a surface mounted electronic part including the semiconductor device 10 is to be mounted, and on the dummy pads 37.

As shown in FIG. 5B, the semiconductor device 10 is mounted on the printed circuit board 30.

Reflow heating is then carried out to form an alloy layer of the solder balls 13, solder paste 25, and pads 22 as shown in FIG. 5C. The solder balls 13 are thus connected to the corresponding pads 22. During the reflow heating, an alloy layer is formed at the interface between each auxiliary pin 14 and the solder 38 and at the interface between each dummy pad 37 and the solder 38. The dummy pads 37 are thus fixed to the corresponding auxiliary pins 14.

The auxiliary pins 14 are composed of a material with a melting point of at least 250° C. The temperature for the reflow heating is lower than 250° C. Consequently, the auxiliary pins 14 do not melt during reflow heating. Therefore, even after the reflow heating, the auxiliary pins 14 and the solder 38 reduce the stress on the corners of the semiconductor device 10.

### THIRD EMBODIMENT

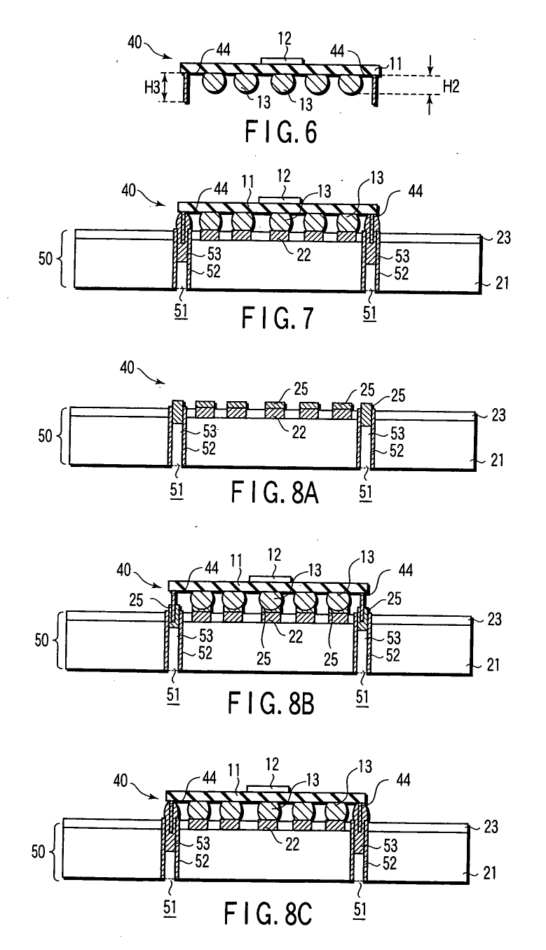

FIGS. 3A to 3D shows a semiconductor device used in a third embodiment. In FIG. 6, the same areas as those in FIGS. 1A to 1C are denoted by the same reference numbers and their description is omitted.

As shown in FIG. 6, auxiliary pins 44 on a semiconductor device 40 in accordance with the present embodiment have a height H3 larger than that H2 of the solder balls 13. The auxiliary pins 44 are composed of a material similar to that of the auxiliary pins 14 used in the first and second embodiments.

FIG. 7 shows the semiconductor substrate 40 mounted on a printed circuit board 50. As shown in FIG. 7, through-holes 51 are formed in the printed circuit board 50. A dummy through-via 52 is formed in a sidewall surface of each of the through-holes 51. The dummy through-via 52 is not electrically connected to the interlayer wiring.

Each auxiliary pin 44 is inserted into the corresponding through-hole 51. Solder 53 is provided in the gap between the auxiliary pin 44 and the dummy through-via 52. An alloy layer is formed at the interface between the auxiliary pin 44 and the solder 53 and at the interface between the dummy through-via 52 and the solder 53.

Since the solder 53 is used to fix the auxiliary pins 44 provided in the corners of the BGA package to the corresponding dummy through-vias 52 formed in the printed circuit board 30, the corners of the semiconductor device 40 are reinforced to reduce the stress on the corners. The solder balls 13 located close to the corners are thus unlikely to undergo microcracking. This improves the reliability of the semiconductor device concerning mechanical stresses.

Now, with reference to FIGS. 8A to 8C, description will be given of a method of mounting the semiconductor device 40 on the printed circuit board 50.

As shown in FIG. 8A, the solder paste 25 is printed on the pads 22, on which a surface mounted electronic part including the semiconductor device 40 is to be mounted, and on the through-holes 51. At this time, the solder paste 25 is preferably filled into the upper parts of the through-holes 51.

As shown in FIG. 8B, the semiconductor device 40 is mounted on the printed circuit board 50. At this time, the auxiliary pins 44 are inserted into the corresponding through-holes 51. The auxiliary pins 44 and the through-holes 51 serve to align the semiconductor 40 with the printed circuit board 50. The semiconductor device 40 may be mounted on the printed circuit board 50 so as to insert the auxiliary pins 44 into the corresponding through-holes 51. Misalignment during mounting causes the semiconductor device 40 to float from the printed circuit board 50. This enables the operator to immediately notice the misalignment.

Reflow heating is then carried out to form an alloy layer of the solder balls 13, solder paste 25, and-pads 22 as shown in FIG. 8C. The solder balls 13 are thus connected to the corresponding pads 22. An alloy layer is also formed at the interface between each auxiliary pin 44 and the solder 53 and at the interface between each dummy through-via 52 and the solder 53. Thus, the auxiliary pin 44 is joined to the solder 53, while the dummy through-via 52 is joined to the solder 53.

The auxiliary pins 44 are composed of a material with a melting point of at least 250° C. The temperature for the reflow heating is lower than 250° C. Consequently, the auxiliary pins 44 do not melt during reflow heating. Therefore, even after the reflow heating, the auxiliary pins 44 and the solder 53 reduce the stress on the corners of the semiconductor device 40.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
an interposer board having a rectangular shape;
a semiconductor chip provided on a front surface of the interposer board;
projecting electrodes provided in a area on a back surface of the interpose board and electrically connected to the semiconductor chip; and
auxiliary pins provided in corners of the back surface of the interposer board which corners are located outside the area, the auxiliary pins having a melting point of at least 250° C.

2. The semiconductor device according to claim 1, wherein the auxiliary pins have a smaller height than that of the projecting electrodes.

3. The semiconductor device according to claim 1, wherein the auxiliary pins have a larger height than that of the projecting electrodes.

4. An electronic part comprising:
a semiconductor device including an interposer board having a rectangular shape, a semiconductor chip provided on a front surface of the interposer board, projecting electrodes provided in a area on a back surface of the interpose board and electrically connected to the semiconductor chip, and auxiliary pins provided in corners of the back surface of the interposer board which corners are located outside the area, the auxiliary pins having a melting point of at least 250°C.;
a printed circuit board on which the semiconductor device is mounted; and
a fixing member which fixes the auxiliary pins to the printed circuit board.

5. The electronic part according to claim 4, wherein the auxiliary pins have a smaller height than that of the projecting electrodes, and
the fixing member is an adhesive.

6. The electronic part according to claim 4, wherein the auxiliary pins have a larger height than that of the projecting electrodes,
the printed circuit board has dummy pads provided at positions corresponding to positions where the auxiliary pins are arranged, and
the fixing member is an solder.

7. The electronic part according to claim 4, wherein the auxiliary pins have a larger height than that of the projecting electrodes,
the printed circuit board has through-holes through which the projecting electrodes are inserted, and
the fixing member is solder.

8. A method for mounting a semiconductor device, the method comprising:
providing a semiconductor device comprising an interposer board having a rectangular shape, a semiconductor chip provided on a front surface of the interposer board, projecting electrodes provided in a area on a back surface of the interpose board and electrically connected to the semiconductor chip, and auxiliary pins provided in corners of the back surface of the interposer board which corners are located outside the area, the auxiliary pins having a melting point of at least 250° C.;
providing a printed circuit board having pads provided at positions corresponding to positions where the projecting electrodes are arranged;
printing solder paste on the pads;
applying a thermosetting adhesive at positions corresponding to the auxiliary pins;
mounting the semiconductor device on the printed circuit board; and
reflow heating the printed circuit board on which the semiconductor device is mounted, at a temperature of lower than 250° C.
